(19) United States
(12) Patent Application Publication
(10) Pub. No.: US 2024/0014092 A1
(43) Pub. Date: Jan. 11, 2024

(54) SEMICONDUCTOR PACKAGE

(71) Applicant: SAMSUNG ELECTRONICS CO., LTD., Suwon-si (KR)

(72) Inventors: YECHUNG CHUNG, Suwon-si (KR); WOONBAE KIM, Suwon-si (KR)

(21) Appl. No.: 18/175,947

(22) Filed: Feb. 28, 2023

(30) Foreign Application Priority Data
Jul. 5, 2022 (KR) 10-2022-0082352

(51) Int. Cl. H01L 23/367; H01L 23/498

(52) U.S. Cl. CPC H01L 23/367; H01L 23/4985; H01L 23/49838; H01L 2224/16225; H01L 24/16

(57) ABSTRACT

A semiconductor package includes a flexible base film, a semiconductor chip on a first surface of the base film, and a heat radiating member on a second surface of the base film. The base film has a recess pattern in the second surface. The recess pattern is adjacent the semiconductor chip. The heat radiating member may be in the recess pattern.

### CROSS-REFERENCE TO RELATED APPLICATION

This U.S. nonprovisional application claims priority under 35 U.S.C. § 119 to Korean Patent Application No. 10-2022-0082352 filed on Jul. 5, 2022 in the Korean Intellectual Property Office, the disclosure of which is hereby incorporated by reference in its entirety.

### FIELD

The present inventive concepts relate to semiconductor packages, and more particularly, to chip-on-chip type semiconductor packages.

### BACKGROUND

In the semiconductor industry, integrated circuit packaging technology has been developed to satisfy requirements for small-form-factor devices and high package reliability. For instance, packaging techniques capable of achieving a chip-size package are actively being developed to satisfy the requirements for small-form-factor devices. Packaging techniques capable of promoting efficiency in a packaging process, as well as improving mechanical and electrical reliability of a packaged product, are desirable.

Chip-on-film (COF) technology is a new type of package that has been developed on a display driver integrated circuit (IC) in keeping with the trend of light, thin, and compact-sized communication equipment. When a high-resolution display device is implemented with COF technology, driving frequencies of televisions and monitors may be increased to increase driving loads of the driver IC, which may result in heat generation from integrated circuits.

### SUMMARY

Some embodiments of the present inventive concepts provide semiconductor packages with increased thermal radiation efficiency.

Some embodiments of the present inventive concepts provide compact-sized semiconductor packages.

Some embodiments of the present inventive concepts provide semiconductor packages with improved warpage resistance and structural stability.

According to some embodiments of the present inventive concepts, a semiconductor package includes a flexible base film, a semiconductor chip on a first surface of the base film, and a heat radiating member on an opposite second surface of the base film. The base film may have a recess pattern in the second surface that overlaps the semiconductor chip. The heat radiating member may be in the recess pattern.

According to some embodiments of the present inventive concepts, a semiconductor package includes a flexible base film, a conductive line on a top surface of the base film, a semiconductor chip on the conductive line, and a metallic heat radiating member in a lower portion of the base film and below the semiconductor chip. A first thickness of the base film between the semiconductor chip and the metallic heat radiating member may be less than a second thickness of the base film on one side of the metallic heat radiating member.

According to some embodiments of the present inventive concepts, a semiconductor package includes a flexible base film having a first surface and an opposite second surface, a conductive line on the first surface of the base film, a surface dielectric layer on the conductive line, a semiconductor chip on the base film and coupled to the conductive line, and a recess pattern in the second surface of the base film. The recess pattern and the semiconductor chip are opposite to each other.

### BRIEF DESCRIPTION OF THE DRAWINGS

FIGS. 1 and 2 illustrate cross-sectional views of a semiconductor package according to some embodiments of the present inventive concepts.

FIG. 3 illustrates a plan view of a semiconductor package according to some embodiments of the present inventive concepts.

FIGS. 4 and 5 illustrate enlarged views of section A of FIG. 1.

FIG. 6 illustrates a cross-sectional view of a semiconductor package according to some embodiments of the present inventive concepts.

FIGS. 7, 8, and 9 illustrate plan views of a semiconductor package according to some embodiments of the present inventive concepts.

FIG. 10 illustrates a plan view of a semiconductor package according to some embodiments of the present inventive concepts.

FIG. 11 illustrates a cross-sectional view of a semiconductor package according to some embodiments of the present inventive concepts.

FIGS. 12 and 13 illustrate cross-sectional views of a semiconductor package according to some embodiments of the present inventive concepts.

FIGS. 14 and 15 illustrate cross-sectional views of a semiconductor package according to some embodiments of the present inventive concepts.

FIGS. 16 and 17 illustrate cross-sectional views of a semiconductor package according to some embodiments of the present inventive concepts.

FIG. 18 illustrates a cross-sectional view of a semiconductor package according to some embodiments of the present inventive concepts.

FIGS. 19, 20, and 21 illustrate cross-sectional views of a method of fabricating a semiconductor package according to some embodiments of the present inventive concepts.

### DETAIL PARTED DESCRIPTION OF EMBODIMENTS

The following will now describe semiconductor packages according to the present inventive concepts with reference to the accompanying drawings.

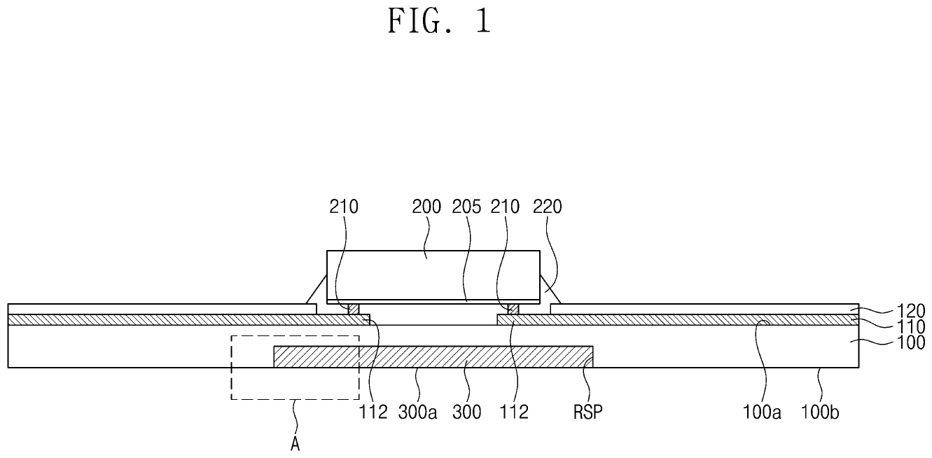

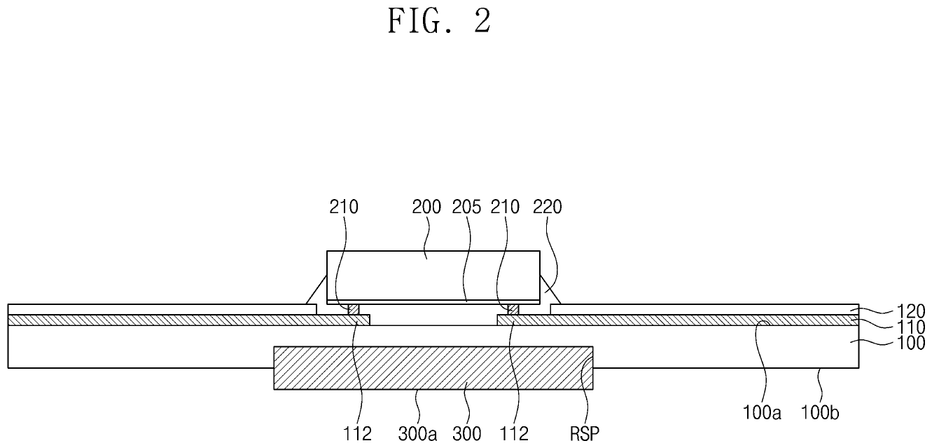

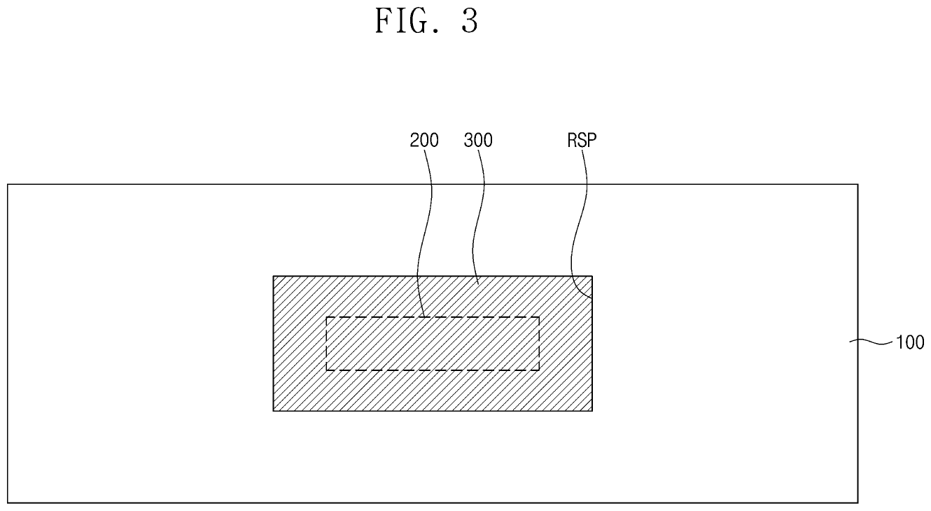

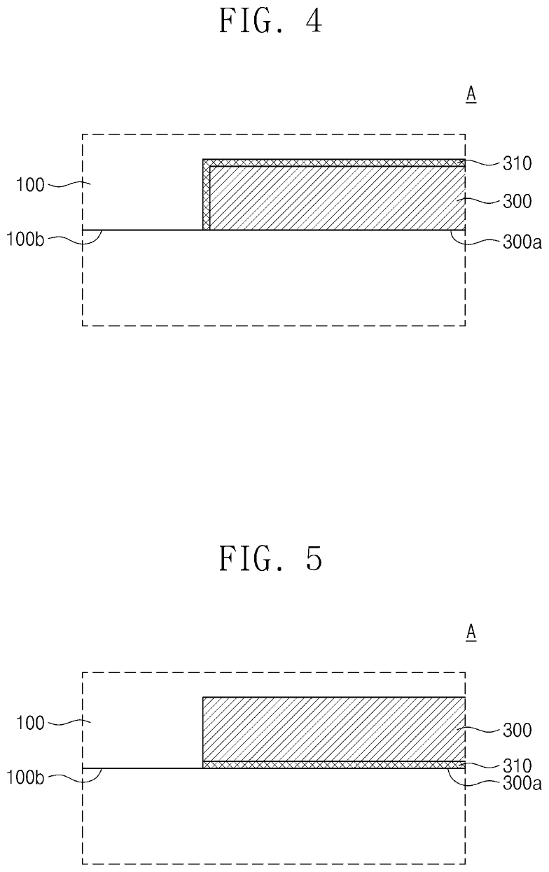

FIGS. 1 and 2 illustrate cross-sectional views of a semiconductor package according to some embodiments of the present inventive concepts. FIG. 3 illustrates a plan view of a semiconductor package according to some embodiments of the present inventive concepts. FIGS. 4 and 5 illustrate enlarged views of section A of FIG. 1.

Referring to FIGS. 1 to 3, a semiconductor package may be a chip-on-film (COF) type semiconductor device.

A base film 100 may be provided. The base film 100 may have a first or front surface 100a and an opposite second or rear surface 100b. In this description, the front surface 100a of the base film 100 may be defined to refer to a surface on which semiconductor chips are mounted or lines and/or pads are formed, and the rear surface 100b of the base film 100 may be defined to refer to a surface opposite to the front surface 100a. The base film 100 may include a dielectric material. The base film 100 may be a flexible film-type substrate. For example, the base film 100 may include a substrate formed of a flexible material such as a flexible film including polyimide or epoxy-based resin.

A semiconductor chip 200 may be mounted on the base film 100. The semiconductor chip 200 may be disposed on the front surface 100a of the base film 100. The semiconductor chip 200 may be flip-chip mounted on the base film 100. For example, a front surface of the semiconductor chip 200 may be directed toward the base film 100. In this description, the front surface of the semiconductor chip 200 may be defined to indicate an active surface on which is formed a circuit layer of the semiconductor chip 200, and a rear surface of the semiconductor chip 200 may be defined to indicate an inactive surface opposite to the front surface of the semiconductor chip 200. For example, the front surface of the semiconductor chip 200 may be a surface on which a circuit layer 205 is provided. The circuit layer 205 may include an integrated circuit provided on the front surface of the semiconductor chip 200. For example, the semiconductor chip 200 may include a semiconductor substrate, and the circuit layer 205 may include the integrated circuit including transistors or passive elements formed on one surface of the semiconductor substrate, and a dielectric layer on the one surface of the semiconductor substrate and covering the integrated circuit. The semiconductor chip 200 may include chip pads 210 that are provided on the front surface of the semiconductor chip 200 and are connected to the circuit layer 205. The chip pads 210 may be directed toward the base film 100.

Conductive lines 110 may be provided between the base film 100 and the semiconductor chip 200. For example, the conductive lines 110 may include lead frames disposed on the front surface 100a of the base film 100. The conductive lines 110 may be disposed separated apart from each other. The conductive lines 110 may extend from a central portion toward an outer portion of the base film 100. The semiconductor chip 200 may be coupled to the conductive lines 110 provided on the front surface 100a of the base film 100. On the central portion of the base film 100, the chip pads 210 of the semiconductor chip 200 may be in direct contact with the conductive lines 110. For example, the conductive lines 110 may be provided on the base film 100 to come into connection with the chip pads 210 of the semiconductor chip 200. On the base film 100, the conductive lines 110 may serve to transmit electrical signals from the semiconductor chip 200 to an external input/output device. In some embodiments, the semiconductor chip 200 may be connected to the conductive lines 110 through connection terminals such as solder balls or solder bumps provided between the chip pads 210 and the conductive lines 110. The conductive lines 110 may include metal, such as copper (Cu).

A surface dielectric layer 120 may further be provided on the base film 100. The surface dielectric layer 120 may be disposed on the front surface 100a of the base film 100. The surface dielectric layer 120 may cover portions of the conductive lines 110 that extend toward an outer side of the semiconductor chip 200. For example, a portion 112 of the conductive lines 110 that is exposed without being covered with the surface dielectric layer 120 may be a pad portion on which the semiconductor chip 200 is mounted. For example, a solder resist layer may be used as the surface dielectric layer 120. The surface dielectric layer 120 may be provided to clad the conductive lines 110.

An under-fill layer 220 may be provided between the base film 100 and the semiconductor chip 200. The under-fill layer 220 may fill a space between the base film 100 and the semiconductor chip 200. The under-fill layer 220 may encapsulate the chip pads 210 and portions 112 of the conductive lines 110. When the semiconductor chip 200 is connected through connection terminals to the conductive lines 110, the under-fill layer 220 may surround the connection terminals between the base film 100 and the semiconductor chip 200. As shown in FIGS. 1 and 2, the under-fill layer 220 may cover a portion of the surface dielectric layer 120. Alternatively, differently from that shown in FIGS. 1 and 2, the under-fill layer 220 may not cover the surface dielectric layer 120. The under-fill layer 220 may include, for example, an anisotropic conductive film (ACF) or a non-conductive paste (NCP).

The base film 100 may have a recess pattern RSP formed in the rear surface 100b of the base film 100 and that is adjacent to the semiconductor chip 200. The recess pattern RSP may have a shape that is recessed from the rear surface 100b of the base film 100 toward the front surface 100a of the base film 100, as illustrated in FIG. 1. For example, the recess pattern RSP may have a bottom surface (i.e., the surface at the bottom of the well/recess) closer than the rear surface 100b of the base film 100 to the front surface 100a of the base film 100. In this sense, the base film 100 may have a smaller thickness at a portion on which the recess pattern RSP is provided and a larger thickness at another portion adjacent to the recess pattern RSP. The recess pattern RSP may have a tetragonal sectional shape. Differently from that shown in FIGS. 1 and 2, the recess pattern RSP may have a trapezoidal sectional shape. In this case, the recess pattern RSP may have a width that increases with increasing distance from the front surface 100a of the base film 100. The recess pattern RSP may overlap the semiconductor chip 200 (i.e., the RSP may have a length and/or width greater than a length and/or width of the semiconductor chip 200). For example, as shown in FIG. 3, the recess pattern RSP may overlap (i.e., extend over) an entirety of the semiconductor chip 200 (i.e., the width and length of the RSP is greater than the width and length of the semiconductor chip 200) when viewed in plan view. The recess pattern RSP may have a rectangular planar shape. Differently from that shown in FIG. 3, the recess pattern RSP may have a polygonal planar shape, a circular planar shape, or any other planar shape. The term “planar shape”, as used herein with respect to the recess pattern RSP, means that the recess pattern RSP has a flat or level surface that continues in all directions.

Referring to FIGS. 1 to 5, a heat radiating member 300 may be provided in the recess pattern RSP. The heat radiating member 300 may fill the recess pattern RSP. For example, the heat radiating member 300 may be buried in a lower portion of the base film 100. As shown in FIG. 1, a bottom surface 300a of the heat radiating member 300 may be coplanar with the rear surface 100b of the base film 100. For example, the bottom surface 300a of the heat radiating member 300 and the rear surface 100b of the base film 100 may be flat as a whole. Alternatively, as shown in FIG. 2, the heat radiating member 300 may protrude from the rear surface 100b of the base film 100. For example, the bottom surface 300a of the heat radiating member 300 may be positioned farther from the front surface 100a of the base film 100 than the rear surface 100b of the base film 100. The heat radiating member 300 may have a plate shape. The term “plate shape”, as used herein with respect to the heat radiating member 300, means that the heat radiating member 300 has a linear, flat shape. In accordance with a planar shape of the recess pattern RSP, the heat radiating member 300 may have a rectangular planar shape. Differently from that shown in FIG. 3, the heat radiating member 300 may have a polygonal planar shape, a circular planar shape, or any other planar shape. In this case, the heat radiating member 300 may have a planar shape that conforms to that of the recess pattern RSP. When the heat radiating member 300 protrudes from the rear surface 100b of the base film 100 as in the embodiment of FIG. 2, the planar shape of the heat radiating member 300 may not be required to be identical to that of the recess pattern RSP, and the planar shapes of the heat radiating member 300 and the recess pattern RSP may be different from each other. The planar shape of the heat radiating member 300 in the embodiment of FIG. 2 may correspond to a planar shape of the heat radiating member 300 externally exposed from the base film 100, or to a planar shape at the bottom surface 300a of the heat radiating member 300 seen when the rear surface 100b of the base film 100 is viewed from under the semiconductor package.

The heat radiating member 300 may include a material whose thermal conductivity is high relative to other components of the semiconductor package. For example, the heat radiating member 300 may have a thermal conductivity greater than that of the base film 100. The heat radiating member 300 may include, for example, a metallic material. For example, the heat radiating member 300 may include aluminum (Al) or copper (Cu).

According to some embodiments of the present inventive concepts, the semiconductor package may be configured such that the recess pattern RSP is formed in the base film 100 and below the semiconductor chip 200, and thus the base film 100 may have a relatively small or comparatively small thickness at a portion below the semiconductor chip 200 when compared with portions of the base film 100 that are not overlapped by the semiconductor chip 200. Therefore, heat generated from the semiconductor chip 200 may be easily discharged through the base film 100. In addition, the recess pattern RSP may be provided therein with the heat radiating member 300 whose thermal conductivity is high. Heat generated from the semiconductor chip 200 may be transferred through the base film 100 to the heat radiating member 300, and the heat may be downwardly discharged through the heat radiating member 300 from the base film 100. Accordingly, the semiconductor package may have an increase in thermal radiation efficiency. Moreover, because the heat radiating member 300 is buried in a lower portion of the base film 100, the semiconductor package may have a small thickness even if the heat radiating member 300 is provided below the base film 100. As a result, the semiconductor package may have a small size. As shown in FIG. 2, within a thickness required for the semiconductor package, the heat radiating member 300 may be provided to have a thickness sufficient enough to outwardly discharge heat generated from the semiconductor chip 200. As a result, the semiconductor package may achieve both a reduction in size and an increase in thermal radiation efficiency.

Referring back to FIGS. 1 to 4, the heat radiating member 300 may have a seed layer 310 provided on a surface of the heat radiating member 300. The seed layer 310 may be interposed between the heat radiating member 300 and the base film 100. The seed layer 310 may be provided on top and lateral surfaces of the heat radiating member 300, as illustrated in FIG. 4. For example, the seed layer 310 may conformally cover the recess pattern RSP of the base film 100. The seed layer 310 may cover bottom and lateral surfaces of the recess pattern RSP. The heat radiating member 300 may fill the remaining portion of the recess pattern RSP, as illustrated in FIG. 4. The seed layer 310 may have a thickness ranging from about 50 Å to about 1,000 Å. The seed layer 310 may include metal, such as gold (Au).

Differently from that shown in FIG. 4, the seed layer 310 may be spaced apart from the bottom surface of the recess pattern RSP. Referring to FIG. 5, the seed layer 310 may be provided on the bottom surface 300a of the heat radiating member 300. The heat radiating member 300 and the seed layer 310 may be sequentially disposed on the bottom surface of the recess pattern RSP. For example, the heat radiating member 300 may be provided on the bottom surface of the recess pattern RSP to fill an upper portion of the recess pattern RSP, and the seed layer 310 may be disposed on the heat radiating member 300 to fill a lower portion of the recess pattern RSP. Thus, in the recess pattern RSP, the heat radiating member 300 may be covered with the seed layer 310. The seed layer 310 may have a bottom surface coplanar with the rear surface 100b of the base film 100.

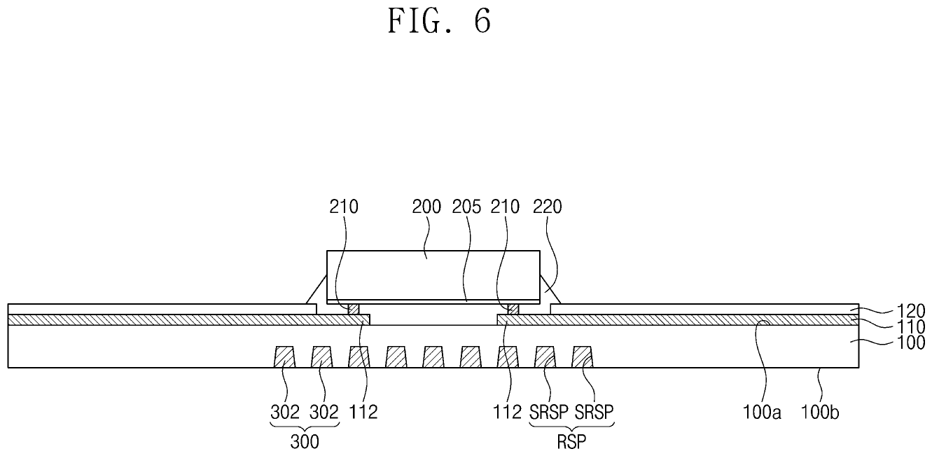

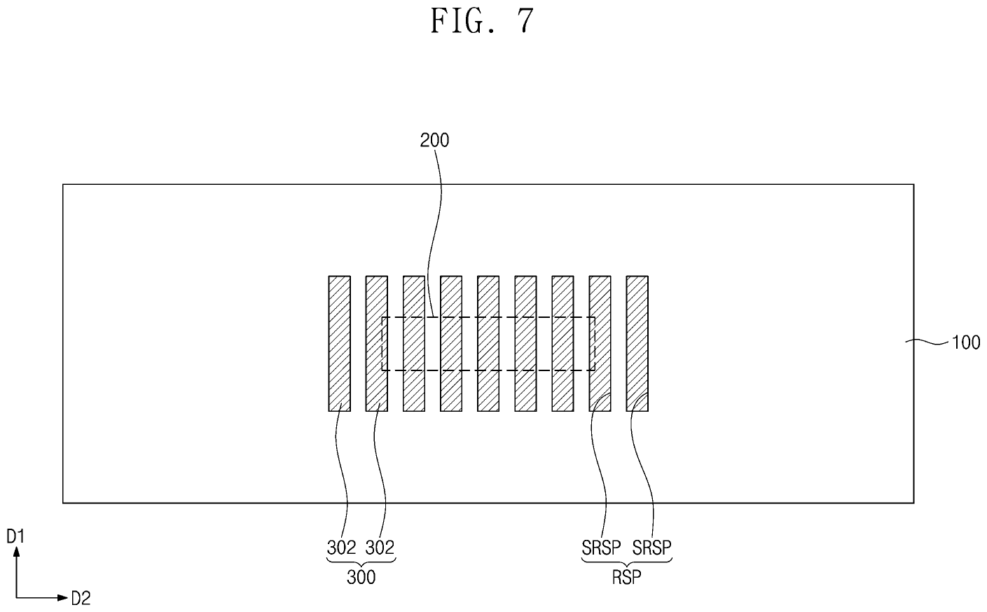

FIG. 6 illustrates a cross-sectional view of a semiconductor package according to some embodiments of the present inventive concepts. FIGS. 7 to 9 illustrate plan views of a semiconductor package according to some embodiments of the present inventive concepts. In the embodiments that follow, a detailed description of technical features repetitive to those discussed with reference to FIGS. 1 to 5 will be omitted for convenience of description, and a difference thereof will be discussed in detail. The same reference numerals will be allocated to the components the same as or similar to those of the semiconductor package discussed above.

FIGS. 1 to 5 depict that one recess pattern RSP is provided in the base film 100 and is filled with or contains one plate-shape heat radiating member 300, but the present inventive concepts are not limited thereto.

Referring to FIG. 6, the recess pattern RSP may have multiple sub-recess patterns SRSP that are disposed spaced apart from each other when viewed in a plan view. Each of the sub-recess patterns SRSP may have a shape that is recessed from the rear surface 100b of the base film 100 toward the front surface 100a of the base film 100. For example, a bottom surface of each of the sub-recess patterns SRSP may be closer than the rear surface 100b of the base film 100 to the front surface 100a of the base film 100. The base film 100 may have a smaller thickness at a portion on which the sub-recess patterns SRSP are provided and a larger thickness at another portion thereof. Each of the sub-recess patterns SRSP may have a trapezoidal sectional shape. In this case, the sub-recess patterns SRSP may have their widths that increase with increasing distance from the front surface 100a of the base film 100. Differently from that shown in FIG. 6, each of the sub-recess patterns SRSP may have a tetragonal sectional shape. At least some of the multiple sub-recess patterns SRSP may overlap or extend beyond the semiconductor chip 200, as illustrated in FIG. 6. For example, as shown in FIG. 7, the sub-recess patterns SRSP extend beyond the ends of the semiconductor chip 200, and a width of the sub-recess patterns SRSP is greater than a width of the semiconductor chip 200.

The recess patterns RSP may have various planar shapes. As shown in FIG. 7, the sub-recess patterns SRSP may extend in a first direction D1 parallel to the rear surface 100b of the base film 100, and may be arranged in a second direction D2 that is parallel to the rear surface 100b of the base film 100 and intersects the first direction D1. For example, the recess pattern RSP may be a stripe pattern that extends in the first direction D1. In such a configuration, the sub-recess patterns SRSP may have the same shape. For example, the sub-recess patterns SRSP may be the same in terms of interval, width, and length. The present inventive concepts, however, are not limited thereto, and if necessary, the sub-recess patterns SRSP may be different in terms of interval, width, and length.

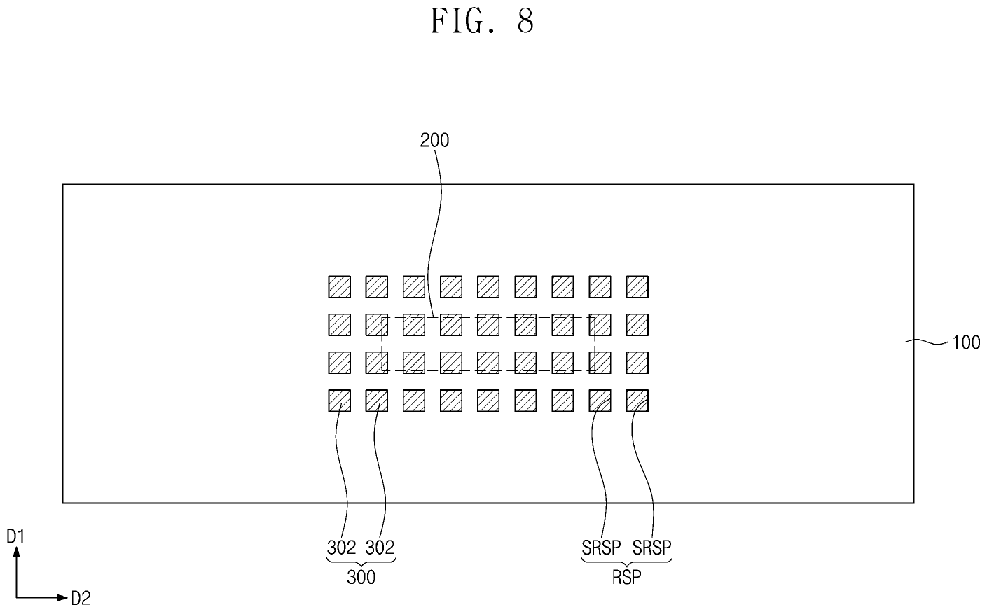

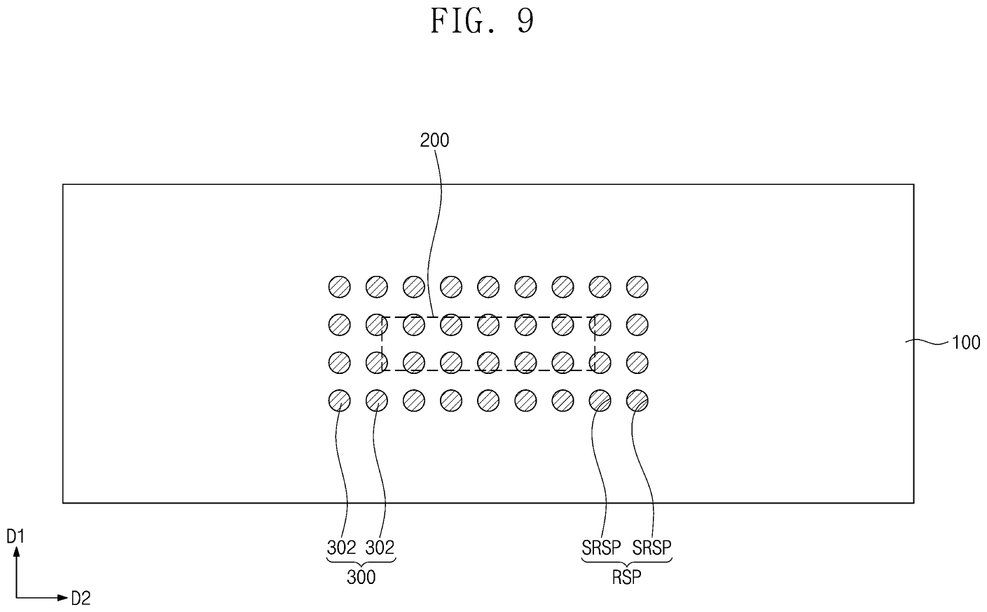

According to some embodiments, as shown in FIGS. 8 and 9, the sub-recess patterns SRSP may be arranged in the first direction D1 and the second direction D2. For example, the recess pattern RSP may include a plurality of recesses arranged in an array along first direction D1 and the second direction D2. As shown in FIG. 8, each of the sub-recess patterns SRSP in the array have a tetragonal shape (e.g., rectangular in cross-section). Alternatively, as shown in FIG. 9, each of the sub-recess patterns SRSP in the array have a cylindrical shape (e.g., circular in cross-section). In some embodiments, each of the sub-recess patterns SRSP in the array may have a polygonal shape in cross-section, a cross shape in cross-section, or any other shape in cross section. In such a configuration, the sub-recess patterns SRSP may all have the same shape. For example, the sub-recess patterns SRSP may be the same in terms of interval, width, period, and planar shape. The present inventive concepts, however, are not limited thereto, and if necessary, the sub-recess patterns SRSP may be different in terms of interval, width, period, and planar shape.

The heat radiating member 300 may be provided in the recess pattern RSP. For example, the heat radiating member 300 may include sub-heat radiating members 302 that correspondingly fill the sub-recess patterns SRSP. In this sense, the sub-heat radiating members 302 may be buried in a lower portion of the base film 100 and may be spaced apart from each other when viewed in a plan view. As shown in FIG. 6, bottom surfaces of the sub-heat radiating members 302 may be coplanar with the rear surface 100b of the base film 100. Thus, the bottom surfaces of the sub-heat radiating members 302 and the rear surface 100b of the base film 100 may be flat as a whole. In accordance with the planar shapes of the sub-recess patterns SRSP, the sub-heat radiating members 302 may have their linear planar shapes, tetragonal planar shapes, circular planar shapes, polygonal planar shapes, or cross planar shapes. For example, as shown in FIG. 7, the plurality of spaced apart sub-heat radiating members 302 may have elongate, linear shapes that extend in the first direction D1. In other words, when viewed in a plan view, this configuration of the heat radiating member 300 may be referred to as a “stripe pattern”. Alternatively, the sub-heat radiating members 302 may have tetragonal planar (i.e., rectangular cross-sectional) shapes arranged in an array as shown in FIG. 8 or cylindrical planar (i.e., circular cross-sectional) shapes arranged in an array as shown in FIG. 9. Thus, when viewed in a plan view, the plurality of heat radiating members 300 arranged in an array may be referred to as a “dot pattern”.

The semiconductor package may be a deformable electronic device such as a flexible device, a foldable device, or a wearable device. Therefore, when an external force is applied to the semiconductor package, the semiconductor package may change in shape. For example, the semiconductor package may be twisted by an external force. For another example, the semiconductor package may be bent or rolled by an external force (i.e., the semiconductor package may be subjected to bending forces and/or compressive forces).

According to some embodiments of the present inventive concepts, the semiconductor package may be configured such that the recess pattern RSP is formed on the base film 100 below the semiconductor chip 200, and that the recess pattern RSP is provided therein with the heat radiating member 300 whose thermal conductivity is high. The semiconductor package may thus have an increase in thermal radiation efficiency. In addition, the recess pattern RSP may include the sub-recess patterns SRSP that are disposed spaced apart from each other, and the sub-heat radiating members 302 of the heat radiating member 300 may also be spaced apart from each other. Accordingly, when the semiconductor package experiences deformation such as warpage, the heat radiating member 300 and the base film 100 may be prevented from being delaminated from each other due to a difference in strength, ductility, and elasticity between the heat radiating member 300 and the base film 100. Hence, as the heat radiating member 300 is provided to the base film 100, the semiconductor package may have an increase in thermal radiation efficiency, warpage properties, and structural stability.

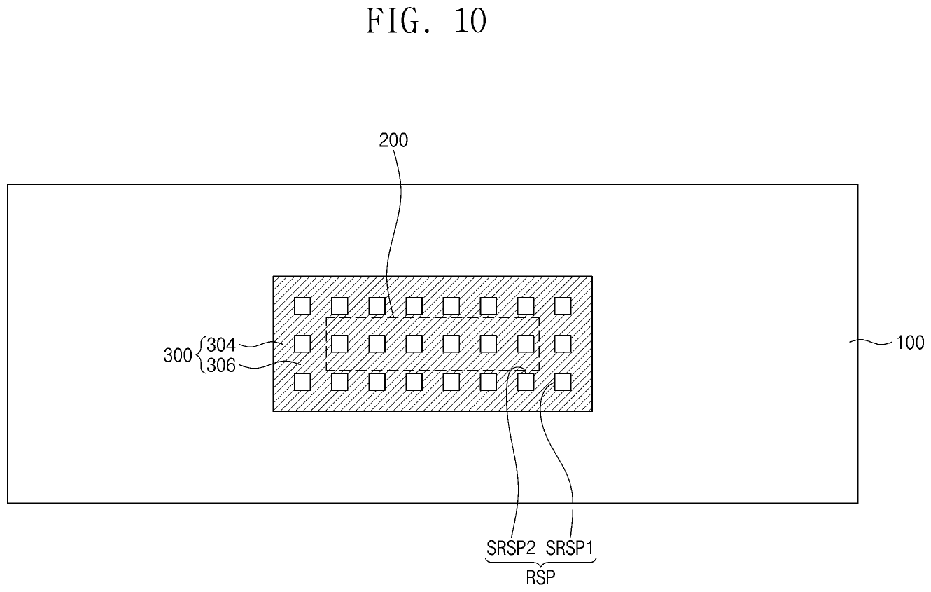

FIG. 10 illustrates a plan view of a semiconductor package according to some embodiments of the present inventive concepts.

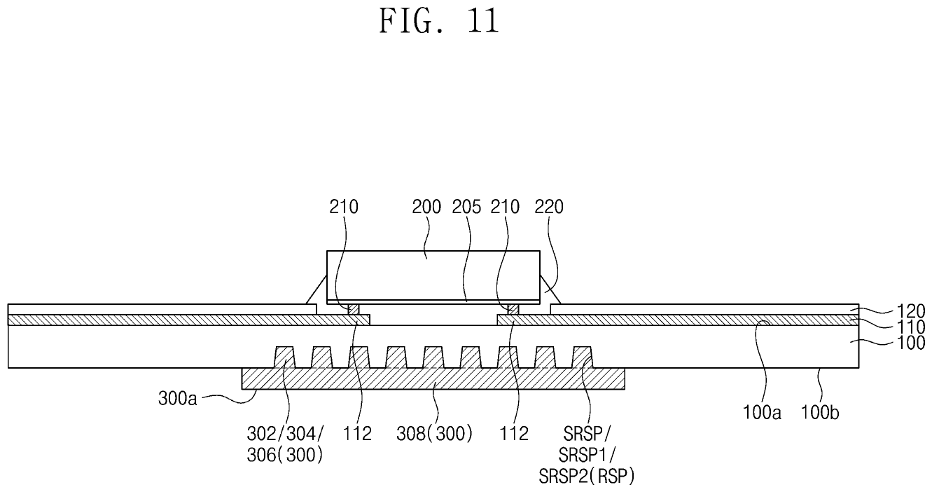

Referring to FIGS. 6 and 10, the recess pattern RSP may include first sub-recess patterns SRSP1 that extend in the first direction D1 and second sub-recess patterns SRSP2 that extend in the second direction D2. Each of the first and second sub-recess patterns SRSP1 and SRSP2 may have a shape that is recessed from the rear surface 100b of the base film 100 toward the front surface 100a of the base film 100. Each of the first and second sub-recess patterns SRSP1 and SRSP2 may have a trapezoidal sectional shape. In this case, each of the first and second sub-recess patterns SRSP1 and SRSP2 may have a width that increases with increasing distance from the front surface 100a of the base film 100, (see, for example, FIG. 11). Alternatively, each of the first and second sub-recess patterns SRSP1 and SRSP2 may have various other tetragonal sectional shapes. At least a portion of the first and second sub-recess patterns SRSP1 and SRSP2 may overlap the semiconductor chip 200. For example, as shown in FIG. 10, the array of sub-recess patterns SRSP1 and SRSP2 may define a length that extends beyond the ends of the semiconductor chip 200, and a width that extends beyond the width of the semiconductor chip 200.

The first sub-recess patterns SRSP1 and the second sub-recess patterns SRSP2 may intersect each other. For example, the recess pattern RSP may be a grid pattern provided along the first direction D1 and the second direction D2. In such a configuration, the first sub-recess patterns SRSP1 may have the same shape, and the second sub-recess patterns SRSP2 may have the same shape. For example, the first sub-recess patterns SRSP1 may be the same in terms of interval, width, and length, and the second sub-recess patterns SRSP2 may be the same in terms of interval, width, and length. The present inventive concepts, however, are not limited thereto, and if necessary, the first sub-recess patterns SRSP1 and the second sub-recess patterns SRSP2 may be different in terms of interval, width, and length.

The heat radiating member 300 may be provided in the recess pattern RSP. For example, the heat radiating member 300 may include first sub-heat radiating members 304 that correspondingly fill the first sub-recess patterns SRSP1 and second sub-heat radiating members 306 that correspondingly fill the second sub-recess patterns SRSP2. In other words, the first sub-heat radiating members 304 and the second sub-heat radiating members 306 may be buried in a lower portion of the base film 100, and the first sub-heat radiating members 304 and the second sub-heat radiating members 306 may be spaced apart from each other when viewed in a plan view. As shown in FIG. 10, bottom surfaces of the first and second sub-heat radiating members 304 and 306 may be coplanar with the rear surface 100b of the base film 100. For example, in accordance with a planar shape of the recess pattern RSP, the first sub-heat radiating members 304 may have their linear shapes that extend in the first direction D1, and the second sub-heat radiating members 306 may have their linear shapes that extend in the second direction D2. Therefore, when viewed in a plan view, the heat radiating member 300 may have a grid pattern provided along the first direction D1 and the second direction D2.

FIG. 11 illustrates a cross-sectional view showing a semiconductor package according to some embodiments of the present inventive concepts.

Referring to FIG. 11, as in the embodiments of FIGS. 6 to 9, the recess pattern RSP may include sub-recess patterns (see SRSP of FIGS. 6 to 9) that are disposed spaced apart from each other when viewed in a plan view. Alternatively, as in the embodiment of FIG. 10, the recess pattern RSP may include first sub-recess patterns (see SRSP1 of FIG. 10) that extend in the first direction D1 and second sub-recess patterns (see SRSP2 of FIG. 10) that extend in the second direction D2 (i.e., the first and second sub-recess patterns are arranged in an array.

The heat radiating member 300 may protrude from the rear surface 100b of the base film 100. For example, the bottom surface 300a of the heat radiating member 300 may be positioned farther than the rear surface 100b of the base film 100 from the front surface 100a of the base film 100. A configuration of the heat radiating member 300 will be further discussed in detail below.

The heat radiating member 300 may have sub-heat radiating members (see 302, 304, and 306 of FIGS. 6 to 10) buried in the base film 100 and an extension 308 positioned on the rear surface 100b of the base film 100. For example, as in the embodiments of FIGS. 6 to 9, the heat radiating member 300 may include sub-heat radiating members 302 that are disposed spaced apart from each other when viewed in a plan view. Alternatively, as in the embodiment of FIG. 10, the heat radiating member 300 may include first sub-heat radiating members (see 304 of FIG. 10) that extend in the first direction D1 and second sub-heat radiating members (see 306 of FIG. 10) that extend in the second direction D2. The extension 308 may overlap the semiconductor chip 200. On the rear surface 100b of the base film 100, the extension 308 may cover an entirety of the sub-heat radiating members 302, 304, and 306. The extension 308 may cover a portion of the rear surface 100b of the base film 100. The sub-heat radiating members 302, 304, and 306 may be connected to the extension 308.

According to some embodiments of the present inventive concepts, as the sub-heat radiating members 302, 304, and 306 are connected to the extension 308 whose area is large, heat transferred from the semiconductor chip 200 to the sub-heat radiating members 302, 304, and 306 may easily be outwardly discharged through the extension 308. Accordingly, the semiconductor package may have an increase in thermal radiation efficiency.

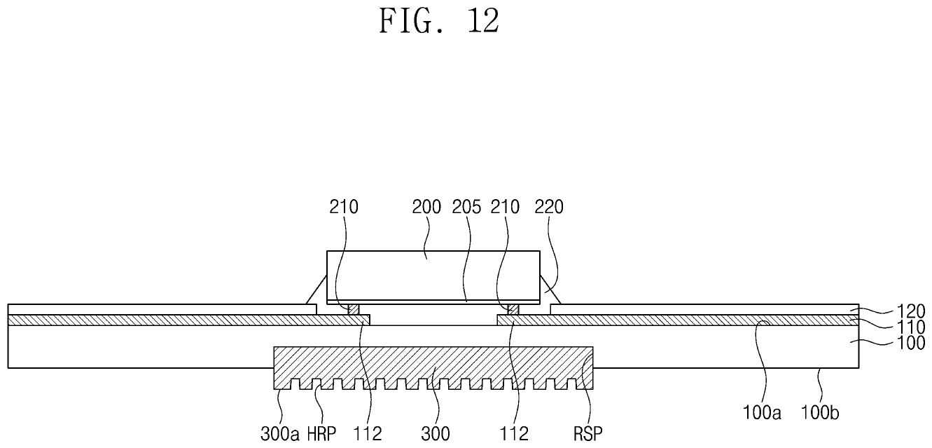

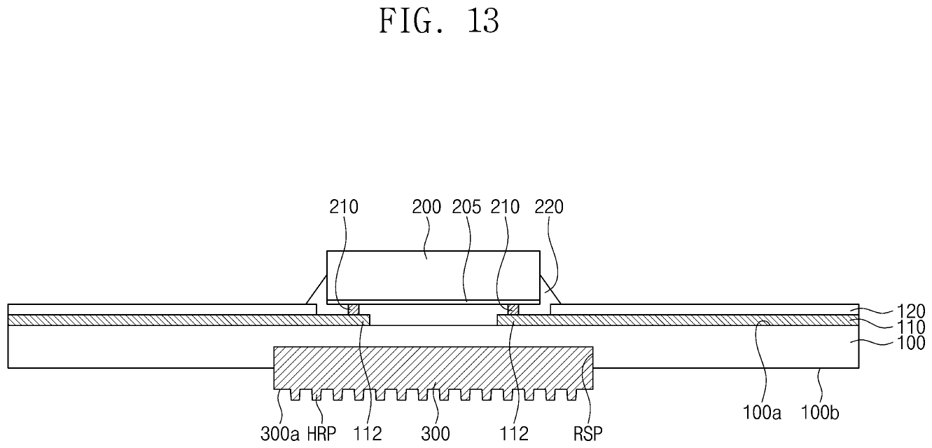

FIGS. 12 and 13 illustrate cross-sectional views of a semiconductor package according to some embodiments of the present inventive concepts.

Referring to FIGS. 12 and 13, the heat radiating member 300 may have a heat radiation pattern HRP formed on the bottom surface 300a of the heat radiating member 300. The heat radiation pattern HRP may be a pattern formed by etching the bottom surface 300a of the heat radiating member 300.

As shown in FIG. 12, the heat radiation pattern HRP may be a pattern that is recessed from the bottom surface 300a of the heat radiating member 300 toward the front surface 100a of the base film 100. For example, a bottom surface of the heat radiation pattern HRP may be closer than the bottom surface 300a of the heat radiating member 300 to a top surface of the heat radiating member 300.

Alternatively, as shown in FIG. 13, the heat radiation pattern HRP may be a pattern that protrudes from the bottom surface 300a of the heat radiating member 300. For example, the bottom surface of the heat radiation pattern HRP may be positioned farther than the bottom surface 300a of the heat radiating member 300 from the top surface of the heat radiating member 300.

When viewed in a plan view, the heat radiation pattern HRP may be a stripe pattern, a dot pattern, or a grid pattern.

According to some embodiments of the present inventive concepts, as the heat radiation pattern HRP is formed on the bottom surface 300a of the heat radiating member 300, there may be a large area in which the heat radiating member 300 is exposed to air. Therefore, heat transferred from the semiconductor chip 200 may easily be outwardly discharged through the heat radiating member 300. Accordingly, the semiconductor package may have an increase in thermal radiation efficiency.

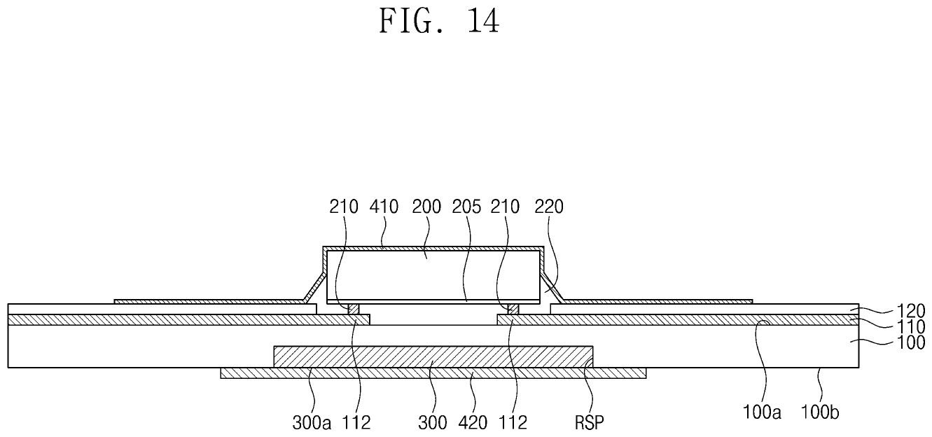

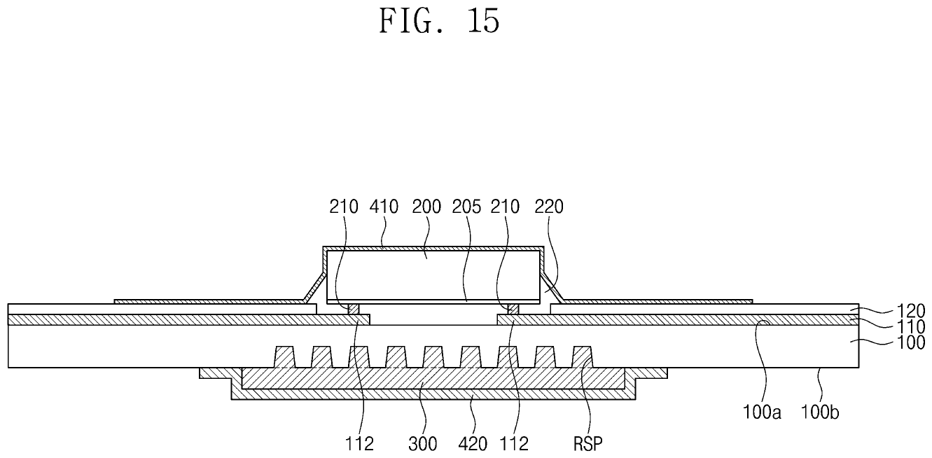

FIGS. 14 and 15 illustrate cross-sectional views of a semiconductor package according to some embodiments of the present inventive concepts.

Referring to FIGS. 14 and 15, the semiconductor package may further include heat transfer films 410 and 420.

A first heat transfer film 410 may be provided on the base film 100. The first heat transfer film 410 may cover the semiconductor chip 200. For example, a central portion of the first heat transfer film 410 may overlap an entirety of the semiconductor chip 200 and may contact a top surface of the semiconductor chip 200. For example, the semiconductor chip 200 may be interposed between the base film 100 and the central portion of the first heat transfer film 410. The first heat transfer film 410 may closely attach the semiconductor chip 200 to the base film 100, and may receive and outwardly discharge heat generated from the semiconductor chip 200.

The first heat transfer film 410 may extend along a lateral surface of the semiconductor chip 200. On the lateral surface of the semiconductor chip 200, the first heat transfer film 410 may cover the under-fill layer 220.

On one side of the semiconductor chip 200, a peripheral portion of the first heat transfer film 410 may be attached to a top surface of the base film 100. For example, the peripheral portion of the first heat transfer film 410 may correspond to a part that attaches the first heat transfer film 410 to the base film 100. Therefore, it may be possible to seal a space between the first heat transfer film 410 and the base film 100, or an internal space defined by the base film 100 and the central portion of the first heat transfer film 410. The peripheral portion of the first heat transfer film 410 may closely attach the semiconductor chip 200 to the base film 100, and the semiconductor chip 200 may be rigidly mounted on the base film 100.

The first heat transfer film 410 may have a planar shape greater than that of the semiconductor chip 200. For example, the first heat transfer film 410 may have a rectangular planar shape. The first heat transfer film 410 may have a thickness ranging, for example, from about 10 μm to about 50 μm. The present inventive concepts, however, are not limited thereto. The thickness of the first heat transfer film 410 may be variously changed in accordance with a configuration and size of the first heat transfer film 410. The first heat transfer film 410 may include a material whose thermal conductivity is high. The first heat transfer film 410 may be formed of a metallic material, such as copper (Cu), aluminum (Al), or stainless steels, or formed of a non-metallic material with high thermal conductivity. When the first heat transfer film 410 is formed of a metallic material, the first heat transfer film 410 may have an electromagnetic shield effect that blocks electromagnetic waves from outside or generated from the semiconductor chip 200. The first heat transfer film 410 may be made of a monolayer film or a multilayer film.

The first heat transfer film 410 may be attached through a first adhesion layer to the base film 100 and the semiconductor chip 200. The first adhesion layer may be provided in the form of an adhesive film or thin film. For example, the first adhesion layer may include an adhesive polymer. For another example, the first adhesion layer may include a material of which thermal conductivity is high or in which are dispersed particles whose thermal conductivity is high. The first adhesion layer may include, for example, a pressure sensitive adhesive (PSA). The first adhesion layer may have a thickness ranging from about 1 μm to about 10 μm. The material and thickness of the first heat transfer film 410 is provided by way of example, and the present inventive concepts are not limited thereto. The first adhesion layer may be formed of various materials and may be provided to have various thicknesses, if necessary.

As in the embodiment of FIG. 1, the base film 100 may be provided with one recess pattern RSP, and the recess pattern RSP may be filled with one heat radiating member 300 having a plate shape (i.e., a linear, flat shape). Alternatively, as in the embodiments of FIGS. 6 to 9, the recess pattern RSP may include multiple sub-recess patterns (see SRSP of FIGS. 6 to 9) that are disposed spaced apart from each other when viewed in a plan view (i.e., arranged in adjacent, spaced apart relationship as in FIGS. 6 and 7 or arranged in an array as in FIGS. 8 and 9), and the heat radiating member 300 may include a corresponding plurality of sub-heat radiating members 302 that fill or are within the sub-recess patterns SRSP. Alternatively, as in the embodiment of FIG. 10, the recess pattern RSP may include first sub-recess patterns (see SRSP1 of FIG. 10) that extend in the first direction D1 and second sub-recess patterns (see SRSP2 of FIG. 10) that extend in the second direction D2, and the heat radiating member 300 may include first sub-heat radiating members 304 and second sub-heat radiating members 306 that fill the first sub-recess patterns SRSP1 and the second sub-recess patterns SRSP2. Alternatively, as in the embodiment of FIG. 11, the heat radiating member 300 may have an extension 308 positioned on the rear surface 100b of the base film 100.

A second heat transfer film 420 may be provided below the base film 100, as illustrated in FIG. 14. On the rear surface 100b of the base film 100, the second heat transfer film 420 may cover the heat radiating member 300, as shown. In such a configuration, the second heat transfer film 420 may cover an entirety of the heat radiating member 300. For example, a central portion of the second heat transfer film 420 may overlap an entirety of the heat radiating member 300, and a peripheral portion of the second heat transfer film 420 may be attached to the rear surface 100b of the base film 100. As shown in FIG. 14, when the heat radiating member 300 is buried in a lower portion of the base film 100, the second heat transfer film 420 may have a flat shape. Alternatively, as shown in FIG. 15, when the heat radiating member 300 protrudes from the rear surface 100b of the base film 100, the second heat transfer film 420 may conformally cover the heat radiating member 300 and the rear surface 100b of the base film 100. For example, the second heat transfer film 420 may contact the bottom surface 300a of the heat radiating member 300, lateral surfaces of the heat radiating member 300, and the rear surface 100b of the base film 100. As such, the second heat transfer film 420 has a non-flat configuration. The second heat transfer film 420 may receive, from the heat radiating member 300, heat generated from the semiconductor chip 200 and then the heat may be outwardly discharged from the second heat transfer film 420.

The second heat transfer film 420 may have a planar shape larger than that of the heat radiating member 300. For example, the second heat transfer film 420 may have a rectangular planar shape. The second heat transfer film 420 may have a thickness ranging, for example, from about 10 μm to about 50 μm. The present inventive concepts, however, are not limited thereto. The thickness of the second heat transfer film 420 may be variously changed in accordance with a configuration, shape, and size of the second heat transfer film 420. The second heat transfer film 420 may include a material whose thermal conductivity is high (e.g., a thermal conductivity greater than a thermal conductivity of other materials of the semiconductor package). The second heat transfer film 420 may be formed of a metallic material, such as copper (Cu), aluminum (Al), or stainless steels, or formed of a non-metallic material with high thermal conductivity. When the second heat transfer film 420 is formed of a metallic material, the second heat transfer film 420 may have an electromagnetic shield effect that blocks electromagnetic waves from outside or generated from the semiconductor chip 200. The second heat transfer film 420 may be made of a monolayer film or a multilayer film. The material and thickness of the second heat transfer film 420 is provided by way of example, and the present inventive concepts are not limited thereto. The second heat transfer film 420 may be formed of various materials and may be provided to have various thicknesses, if necessary.

The second heat transfer film 420 may be attached through a second adhesion layer to the base film 100 and the heat radiating member 300. The second adhesion layer may be provided in the form of an adhesive film or thin film. For example, the second adhesion layer may include an adhesive polymer. For another example, the second adhesion layer may include a material of which thermal conductivity is high or in which are dispersed particles whose thermal conductivity is high. The second adhesion layer may include, for example, a pressure sensitive adhesive (PSA). The second adhesion layer may have a thickness ranging from about 1 μm to about 10 μm.

According to some embodiments of the present inventive concepts, the first hear transfer film 410 and the second heat transfer film 420 may be respectively attached to the front surface 100a and the rear surface 100b of the base film 100. As a result, the semiconductor package may have an increase in thermal radiation efficiency.

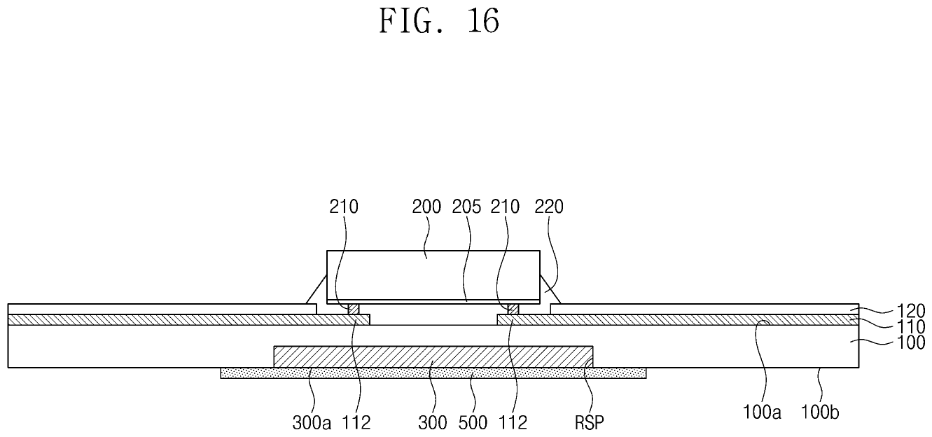

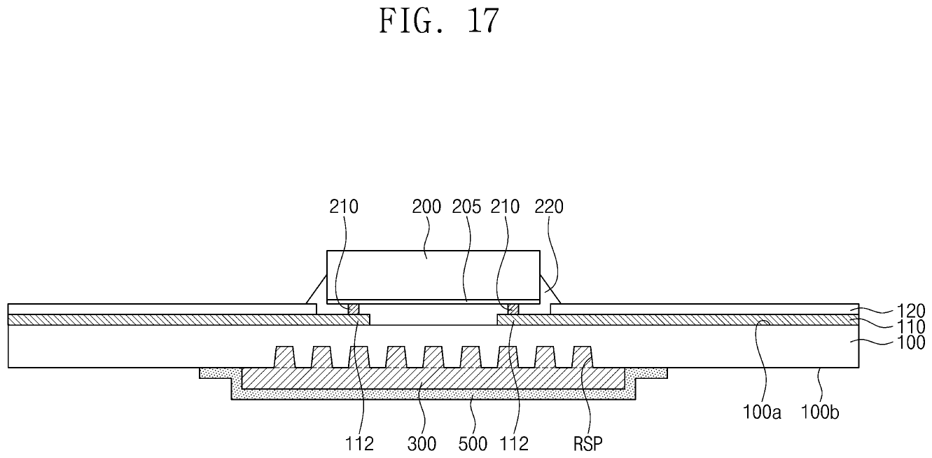

FIGS. 16 and 17 illustrate cross-sectional views of a semiconductor package according to some embodiments of the present inventive concepts.

Referring to FIGS. 16 and 17, the semiconductor package may further include a protection layer 500 on the rear surface 100b of the base film 100. The protection layer 500 may cover the heat radiating member 300. In such a configuration, the protection layer 500 may cover an entirety of the heat radiating member 300. For example, a central portion of the protection layer 500 may overlap an entirety of the heat radiating member 300, and a peripheral portion of the protection layer 500 may be attached to the rear surface 100b of the base film 100. As shown in FIG. 16, when the heat radiating member 300 is buried in a lower portion of the base film 100, the protection layer 500 may have a flat shape. Alternatively, as shown in FIG. 17, when the heat radiating member 300 is provided to protrude from the rear surface 100b of the base film 100, the protection layer 500 may conformally cover the heat radiating member 300 and the rear surface 100b of the base film 100, and have a non-flat configuration. For example, the protection layer 500 may contact the bottom surface 300a of the heat radiating member 300, lateral surfaces of the heat radiating member 300, and the rear surface 100b of the base film 100. The protection layer 500 may be provided to protection the base film 100 and the heat radiating member 300.

The protection layer 500 may have a planar shape larger than that of the heat radiating member 300. For example, the protection layer 500 may have a rectangular planar shape. The protection layer 500 may have a thickness ranging, for example, from about 10 μm to about 30 μm. The present inventive concepts, however, are not limited thereto. The protection layer 500 may include polyimide (PI). Alternatively, the protection layer 500 may be formed of a metallic material, such as copper (Cu), aluminum (Al), or stainless steels. When the protection layer 500 is formed of a metallic material, the protection layer 500 may serve as an electromagnetic shield to block electromagnetic waves from outside or generated from the semiconductor chip 200. The material and thickness of the protection layer 500 is provided by way of example, and the present inventive concepts are not limited thereto. The protection layer 500 may be formed of various materials and may be provided to have various thicknesses, if necessary.

Although not shown, the protection layer 500 may be attached to the base film 100 and the heat radiating member 300 by an adhesion layer. The adhesion layer may be provided in the form of an adhesive film or thin film. For example, the adhesion layer may include an adhesive polymer. For another example, the adhesion layer may include a material of which thermal conductivity is high or in which are dispersed particles whose thermal conductivity is high. The adhesion layer may include, for example, a pressure sensitive adhesive (PSA). The adhesion layer may have a thickness ranging from about 1 μm to about 10 μm.

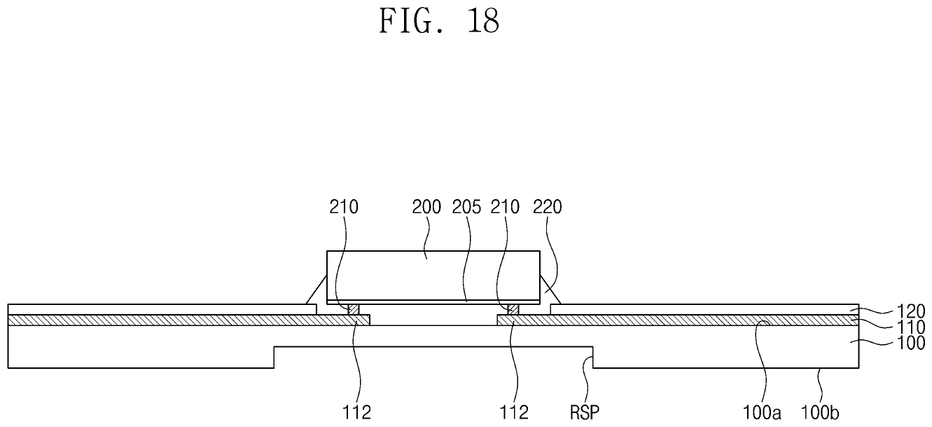

FIG. 18 illustrates a cross-sectional view showing a semiconductor package according to some embodiments of the present inventive concepts.

Referring to FIG. 18, a semiconductor package may include no heat radiating member.

A base film 100 may be provided. The base film 100 may have a front surface 100a and a rear surface 100b. The base film 100 may be a flexible film-type substrate.

A semiconductor chip 200 may be mounted on the base film 100. Conductive lines 110 may be provided between the base film 100 and the semiconductor chip 200. The semiconductor chip 200 may include chip pads 210 in direct contact with the conductive lines 110 on a central portion of the base film 100. A surface dielectric layer 120 may further be provided on the base film 100. An under-fill layer 220 may be provided between the base film 100 and the semiconductor chip 200.

The base film 100 may have a recess pattern RSP formed in the rear surface 100b of the base film 100. The recess pattern RSP may have a shape that is recessed from the rear surface 100b of the base film 100 toward the front surface 100a of the base film 100. For example, the base film 100 may have a smaller thickness at a portion in which the recess pattern RSP is provided and a larger thickness at another portion adjacent to the recess pattern RSP. As discussed above with reference to FIGS. 3 and 7 to 10, the recess pattern RSP may have a tetragonal planar shape, a polygonal planar shape, a circular planar shape, or any other planar shape.

According to some embodiments of the present inventive concepts, the semiconductor package may be configured such that the recess pattern RSP is formed on the base film 100 and below the semiconductor chip 200, and the base film 100 may have a small thickness at a portion directly below the semiconductor chip 200. Therefore, heat generated from the semiconductor chip 200 may be easily discharged through the base film 100.

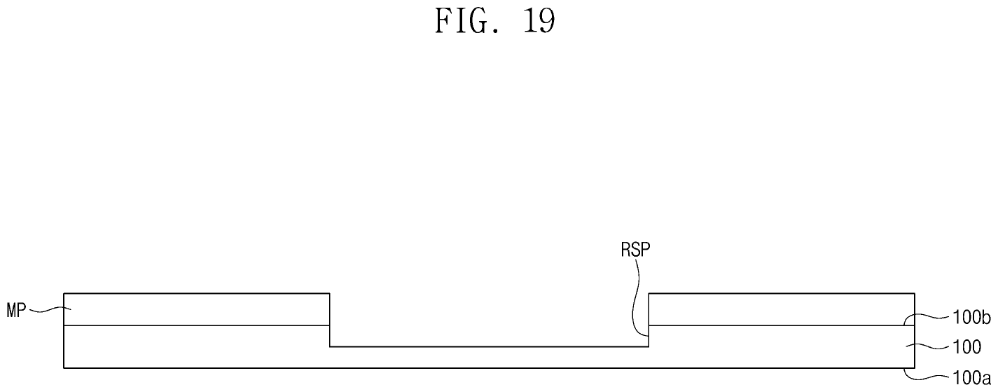

FIGS. 19 to 21 illustrate cross-sectional views of a method of fabricating a semiconductor package according to some embodiments of the present inventive concepts.

Referring to FIG. 19, a base film 100 may be provided. The base film 100 may have a front surface 100a and a rear surface 100b. The base film 100 may be a flexible film-type substrate. For example, the base film 100 may include a substrate formed of a flexible material such as a flexible film including polyimide or epoxy-based resin.

A mask pattern MP may be provided on the rear surface 100b of the base film 100. The mask pattern MP may have a pattern that exposes a central portion of the base film 100. The mask pattern MP may be used to etch the base film 100. Therefore, a recess pattern RSP may be formed on the rear surface 100b of the base film 100.

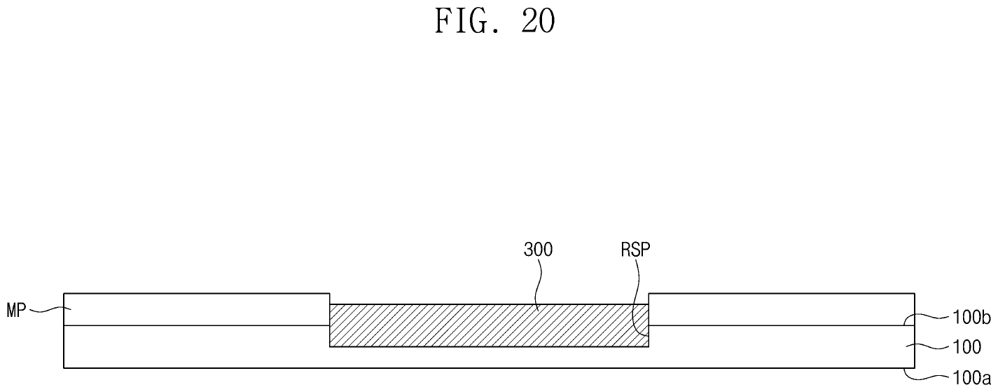

Referring to FIG. 20, a heat radiating member 300 may be formed in the recess pattern RSP. A plating process may be performed to form the heat radiating member 300. For example, a seed layer may be formed on the mask pattern MP. The seed layer may conformally cover a top surface of the mask pattern MP, an inside of the mask pattern MP, and an inside of the recess pattern RSP. The seed layer may be used to perform the plating process. The plating process may continue until the heat radiating member 300 entirely fills the recess pattern RSP. In this step, the heat radiating member 300 may be formed to have a top surface at a higher level than that of the rear surface 100b of base film 100. Alternatively, the heat radiating member 300 may be formed to have a top surface coplanar with the rear surface 100b of base film 100.

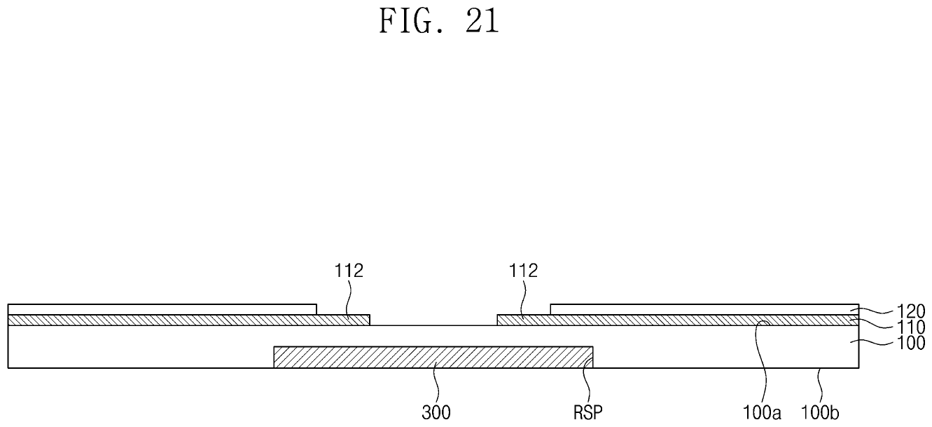

Referring to FIG. 21, the mask pattern MP may be removed. For example, the rear surface 100b of the base film 100 may undergo a thinning process to remove the mask pattern MP. In this step, the heat radiating member 300 may have a portion that protrudes from the rear surface 100b of the base film 100, and the protruding portion of the heat radiating member 300 may be removed together with the mask pattern MP. In this case, the heat radiating member 300 may have one surface coplanar with the rear surface 100b of the base film 100. Alternatively, an etching process may be employed to remove only the mask pattern MP. In this case, the heat radiating member 300 may protrude from the rear surface 100b of the base film 100.

There is explained an example of the formation in which the heat radiating member 300 is formed on the base film 100, but the present inventive concepts are not limited thereto. Various methods and process may be adopted to form the heat radiating member 300 on the base film 100.

Referring still to FIG. 21, conductive lines 110 may be formed on the base film 100. For example, a conductive layer may be formed on the front surface 100a of the base film 100, and then the conductive layer may be patterned to form the conductive lines 110.

Afterwards, a surface dielectric layer 120 may be formed on the base film 100. For example, a dielectric layer may be formed on the front surface 100a of the base film 100 so as to cover the conductive lines 110, and then the dielectric layer may be patterned to form the surface dielectric layer 120.

Referring back to FIG. 1, a semiconductor chip 200 may be mounted on the base film 100. Chip pads 210 of the semiconductor chip 200 may be connected to the conductive lines 110 exposed by the surface dielectric layer 120.

An under-fill material may be injected to form an under-fill layer 220 between the base film 100 and the semiconductor chip 200.

In a semiconductor package according to some embodiments of present inventive concepts, a base film is thinner at a location directly below a semiconductor chip. In addition, heat generated from the semiconductor chip may be transferred to a heat radiating member, and the heat may be downwardly discharged through the heat radiating member from the base film. Accordingly, the semiconductor package may have an increase in thermal radiation efficiency. In addition, even if the heat radiating member is provided below the base film, the semiconductor package may have a reduced thickness. As a result, the semiconductor package may have a reduced size. The heat radiating member may be provided to have a thickness sufficient enough to outwardly discharge heat generated from the semiconductor chip. The semiconductor package may be provided to satisfy both a reduction in size and an increase in thermal radiation efficiency.

Moreover, when the semiconductor package experiences deformation such as warpage, the heat radiating member and the base film may be prevented from being delaminated from each other due to a difference in strength, ductility, and elasticity between the heat radiating member and the base film Hence, as the heat radiating member is provided to the base film, the semiconductor package may have an increase in thermal radiation efficiency, a reduction of warpage, and an increase in structural stability.

Although the present inventive concepts have been described in connection with some embodiments of the present inventive concepts illustrated in the accompanying drawings, it will be understood by one of ordinary skill in the art that variations in form and detail may be made therein without departing from the present inventive concepts. The above disclosed embodiments should thus be considered illustrative and not restrictive.

What is claimed is:

1. A semiconductor package, comprising:
a flexible base film;
a semiconductor chip on a first surface of the base film; and
a heat radiating member on an opposite second surface of the base film,
wherein the base film comprises a recess pattern in the second surface, the recess pattern overlapping the semiconductor chip, and
wherein the heat radiating member is in the recess pattern.

2. The semiconductor package of claim 1, wherein a bottom surface of the heat radiating member is coplanar with the second surface of the base film.

3. The semiconductor package of claim 1, wherein a portion of the heat radiating member protrudes from the second surface of the base film.

4. The semiconductor package of claim 1, wherein, when viewed in a plan view, the heat radiating member extends over the semiconductor chip.

5. The semiconductor package of claim 1, wherein
at least one recess of the recess pattern has a rectangular shape, a circular shape, or a polygonal shape, or
when viewed in a plan view, the recess pattern comprises a plurality of spaced apart elongate recesses, or a plurality of recesses arranged in an array.

6. The semiconductor package of claim 1, wherein the heat radiating member comprises metal.

7. The semiconductor package of claim 1, further comprising a seed layer between the heat radiating member and bottom and inner lateral surfaces of the recess pattern.

8. The semiconductor package of claim 1, wherein the heat radiating member comprises a heat radiation pattern on a bottom surface of the heat radiating member, the bottom surface of the heat radiating member being opposite to the base film first surface,
wherein the heat radiation pattern protrudes from or is recessed within the bottom surface of the heat radiating member.

9. The semiconductor package of claim 1, further comprising at least one selected from:
a first heat transfer film on the second surface of the base film, the first heat transfer film extending over the heat radiating member; and
a second heat transfer film on the first surface of the base film, the second heat transfer film extending over the semiconductor chip.

10. A semiconductor package, comprising:
a flexible base film;
a conductive line on a top surface of the base film;
a semiconductor chip on the conductive line; and
a metallic heat radiating member in a lower portion of the base film and below the semiconductor chip,
wherein a first thickness of the base film between the semiconductor chip and the metallic heat radiating member is less than a second thickness of the base film on one side of the metallic heat radiating member.

11. The semiconductor package of claim 10, wherein
the base film comprises a recess pattern in a bottom surface of the base film, and
the metallic heat radiating member is in the recess pattern.

12. The semiconductor package of claim 10, wherein a bottom surface of the metallic heat radiating member is coplanar with a bottom surface of the base film.

13. The semiconductor package of claim 10, wherein a portion of the metallic heat radiating member protrudes from a bottom surface of the base film.

14. The semiconductor package of claim 10, wherein the metallic heat radiating member comprises a plurality of heat radiating members in adjacent, spaced apart relationship.

15. The semiconductor package of claim 10, further comprising a seed layer between the base film and the metallic heat radiating member.

16. The semiconductor package of claim 10, further comprising at least one selected from:
a first heat transfer film on the top surface of the base film, the first heat transfer film extending over the metallic heat radiating member; and
a second heat transfer film on a bottom surface of the base film, the second heat transfer film extending over the semiconductor chip.

17. A semiconductor package, comprising:
a flexible base film comprising a first surface and an opposite second surface;
a conductive line on the first surface of the base film;
a surface dielectric layer on the conductive line;
a semiconductor chip on the base film and coupled to the conductive line; and
a recess pattern in the second surface of the base film,
and
wherein the recess pattern and the semiconductor chip are opposite to each other.

18. The semiconductor package of claim 17, further comprising:
a heat radiating member within the recess pattern; and
a seed layer between the heat radiating member and bottom and inner lateral surfaces of the recess pattern.

19. The semiconductor package of claim 18, wherein
a bottom surface of the heat radiating member is coplanar with the second surface of the base film, or
a portion of the heat radiating member protrudes from the second surface of the base film.

20. The semiconductor package of claim 18, wherein the heat radiating member comprises a plurality of heat radiating members in adjacent, spaced apart relationship.
